(19) United States
(12) Patent Application Publication
(10) Pub. No.: US 2026/0047056 A1
(43) Pub. Date: Feb. 12, 2026

(54) SEMICONDUCTOR DEVICE AND METHOD

(71) Applicant: Taiwan Semiconductor Manufacturing Co., Ltd., Hsinchu (TW)

(72) Inventors: Shih-Hao Lin, Hsinchu (TW); Chih-Hsiang Huang, Zhubei City (TW)

(21) Appl. No.: 18/799,397

(22) Filed: Aug. 9, 2024

(51) Int. Cl. H10B 10/00; H01L 21/8238; H01L 27/092; H01L 29/06; H01L 29/08; H01L 29/423; H01L 29/66; H01L 29/775; H01L 29/786

(52) U.S. Cl. CPC H10B 10/12; H10D 30/014; H10D 30/43; H10D 30/6735; H10D 30/6757; H10D 62/121; H10D 62/151; H10D 64/017; H10D 84/0167; H10D 84/017; H10D 84/038; H10D 84/85

(57) ABSTRACT

In an embodiment, a method may include forming a multi-layer stack over a substrate, the multi-layer stack having alternating layers of first semiconductor layers and second semiconductor layers. The method may also include removing the first semiconductor layers in a first region of the substrate. The method may include forming a disposable material between the second semiconductor layers in the first region. The method may include forming source/drain regions adjacent to the second semiconductor layers and the disposable material in the first region. The method may include replacing the disposable material in the first region with metal gate structures, each of the second semiconductor layers having a different thickness.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2A, 2B, 3, 4, 5, 6A, 6B, 7A, 7B 8A, 8B, 9A, 9B, 10A, 10B, 11A, 11B,, 12A, 12B, 13A, 13B, 13C, 13D, 14A, 14B, 14C, 14D, 15A, 15B, 15C, 16A, 16B, 17A, 17B, 18A, 18B, 19A, 19B, 19C, 19D, 19E, 20A, 20B, 20C, 21A, 21B, 21C, 22A, 22B, and 22C are cross-sectional views of intermediate stages in the manufacturing of nano-FETs, in accordance with some embodiments.

FIGS. 23A, 23B, and 23C are cross-sectional views of a nano-FET, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a process for enhancing data retention in Static Random Access Memory (SRAM) devices, particularly those utilizing technologies nodes smaller than 10 nm. This process, referred to as the Disposable Oxide Interposer (DOI) process, is designed to address the technical problem of nonuniform Silicon (Si) sheet heights in SRAM devices, which often resulted in increased variability in the threshold voltage (Vt) across the device population and a higher minimum operating supply voltage (Vccmin) for the SRAM cells in advanced technology devices.

The DOI process involves engineering the height of Si sheets in the SRAM device by utilizing a Disposable Oxide Interposer. The process includes the removal of SiGe layers from the Si/SiGe multilayer stack, followed by filling the area where SiGe was removed with oxide (DOI). The oxide is then recessed or trimmed to be vertically between Si sheets, but not in source/drain areas. Inner spacers are deposited and trimmed on the sidewalls of the recessed oxide. The recessed oxide is removed when the dummy gate and dummy gate dielectric are removed in the replacement gate process. This process results in improved uniformity of the Si sheet heights.

The DOI process disclosed herein also enables the transition from all same Vt devices to low, median, and high Vt devices, resulting in several potential improvements: enhanced SRAM data retention; improved SRAM Vccmin; reduced power consumption; and reduced cell area.

Furthermore, the DOI process eliminates germanium (Ge) impurity sources at the source/drain etch stage, minimizing sheet-width loss at the final sheet-release stage.

The disclosed process addresses the limitations associated with prior practices that exhibited nonuniform sheet height, which often resulted in restrictions in variability of the Vt and Vccmin. By improving the uniformity of the Si sheet heights and eliminating Ge impurity sources at the source/drain etch stage, the DOI process overcomes these limitations, offering enhancements in SRAM performance such as reduced variability in the threshold voltage (Vt) across the device and a lower minimum operating supply voltage (Vccmin) for the SRAM cells, particularly for technologies smaller than 10 nm.

In the following detailed description, various aspects of the DOI process will be discussed, including the steps involved in engineering the Si sheet height, the transition from all same Vt devices to low, median, and high Vt devices, and the elimination of Ge impurity sources at the source/drain etch stage. The potential benefits of this process, such as improved SRAM data retention, SRAM Vccmin, reduced power consumption, and reduced cell area, will also be explored in detail.

Embodiments are described below in a particular context, a die comprising nano-FETs. Various embodiments may be applied, however, to dies comprising other types of transistors (e.g., fin field effect transistors (FinFETs), planar transistors, or the like) in combination with the nano-FETs.

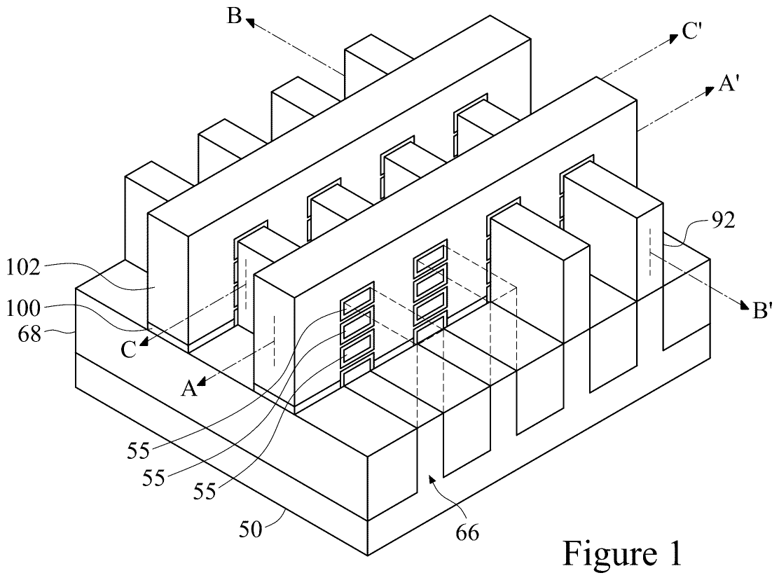

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

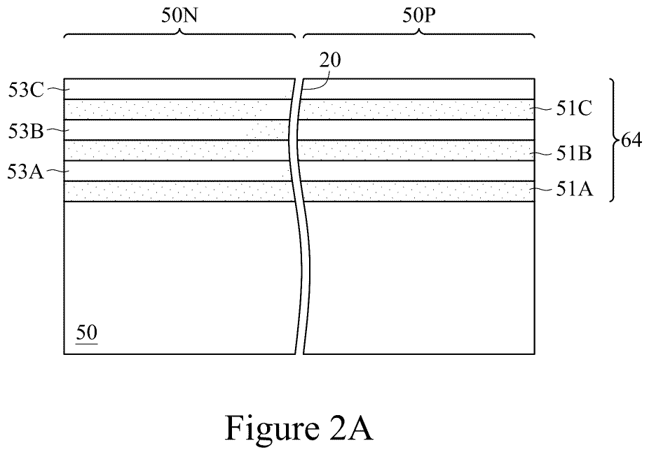

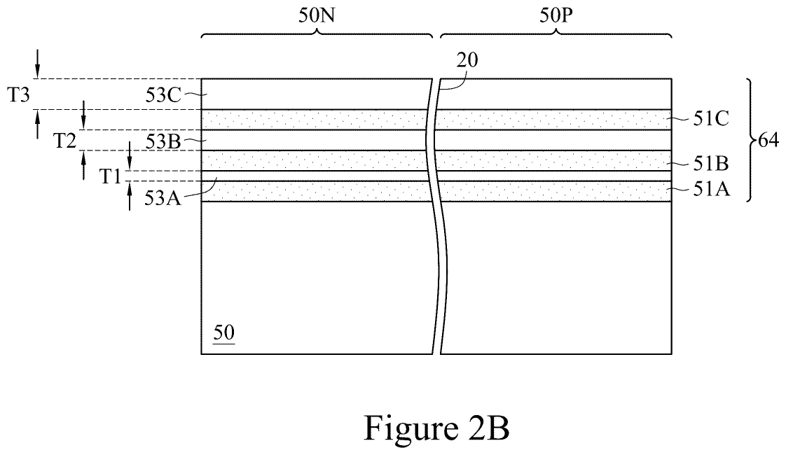

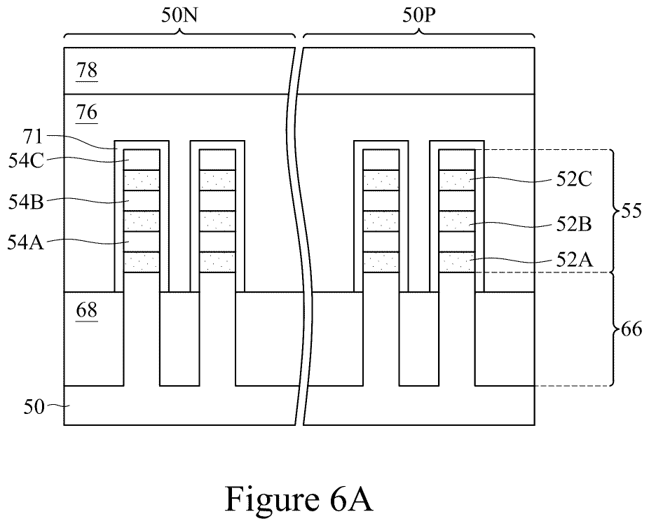

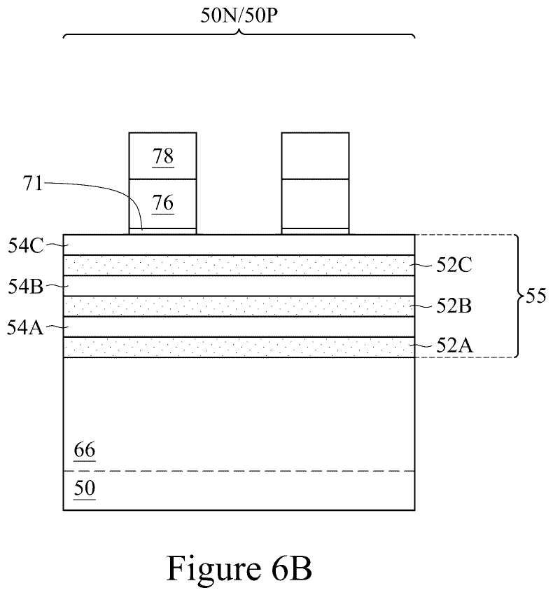

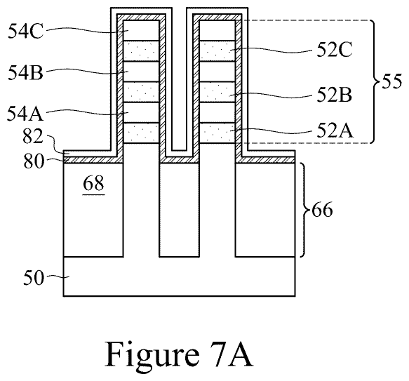

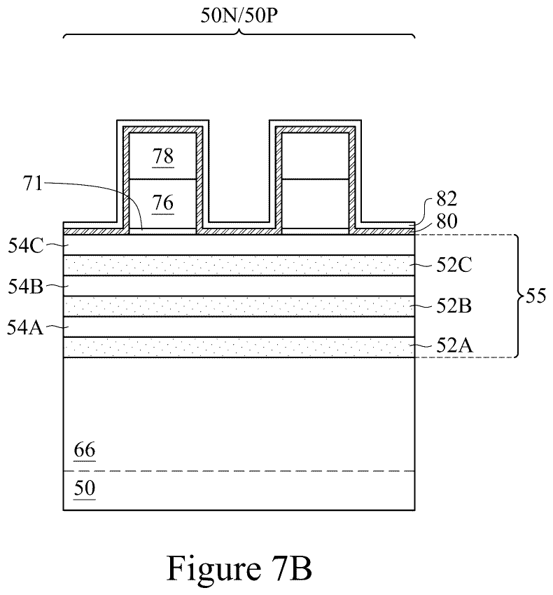

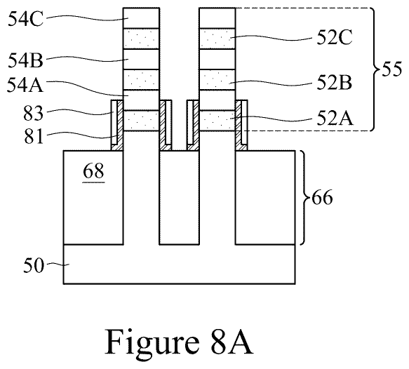

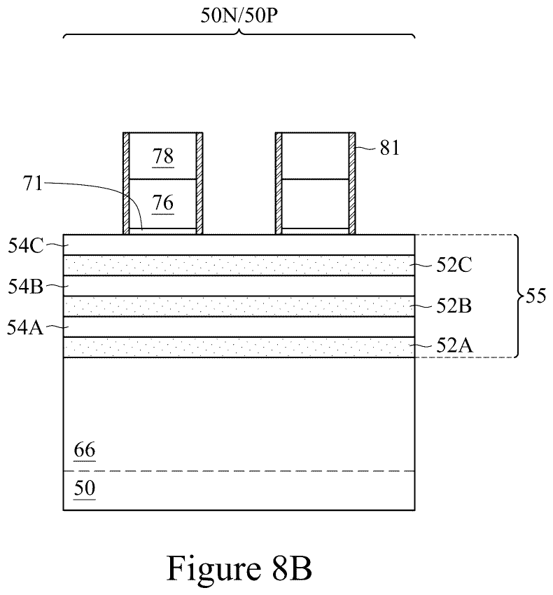

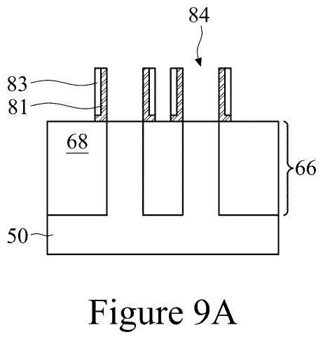

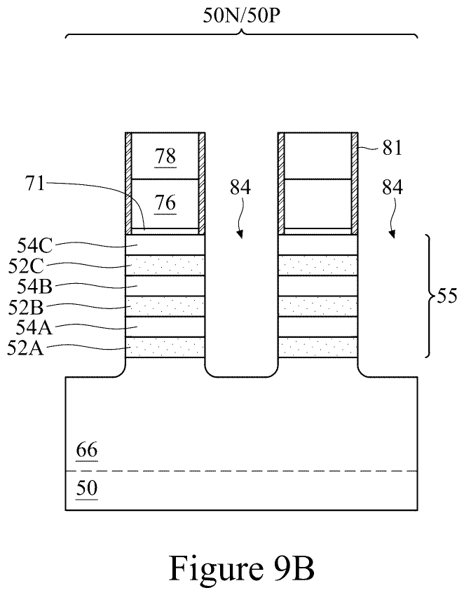

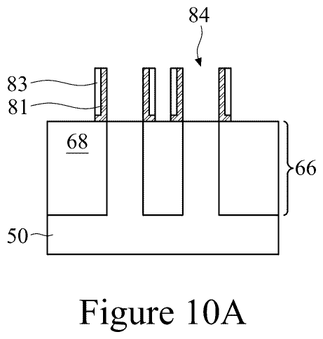

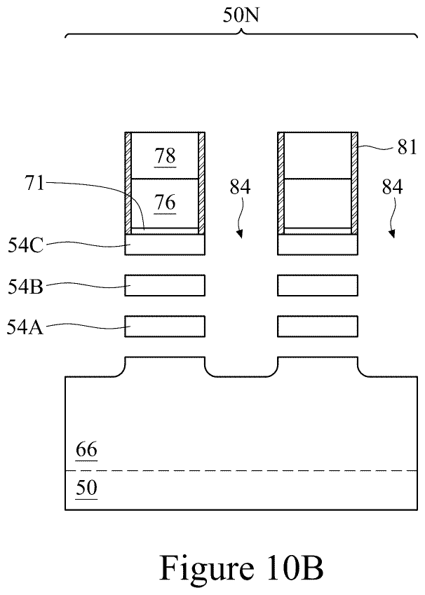

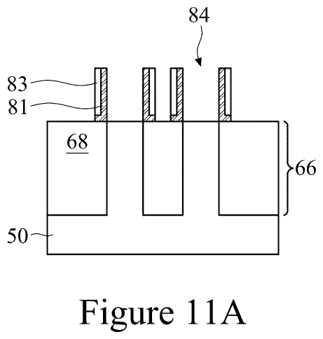

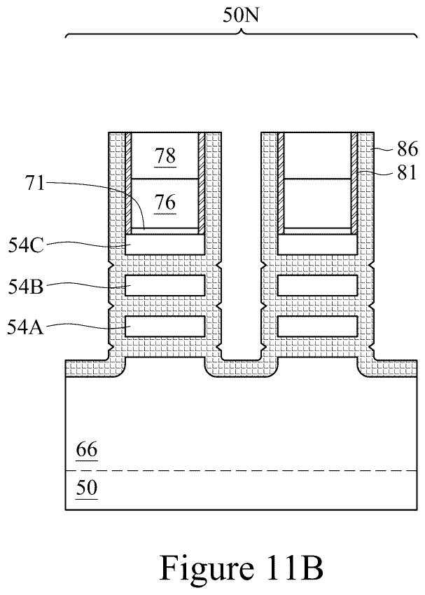

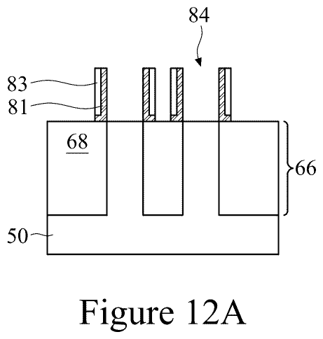

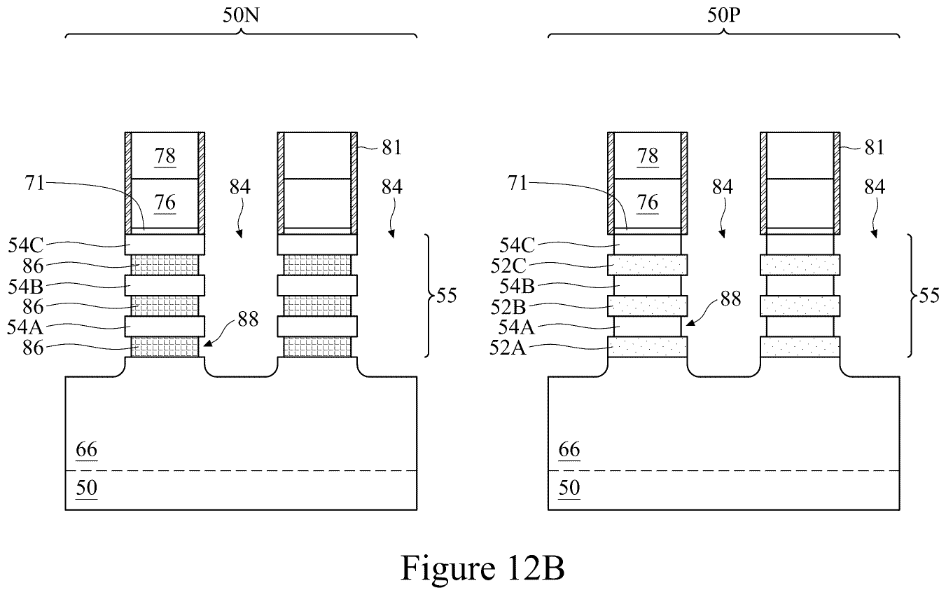

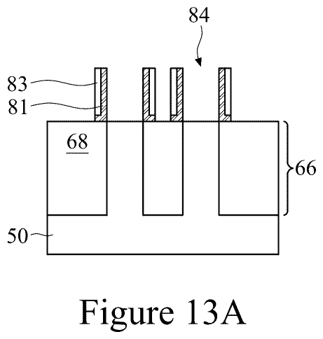

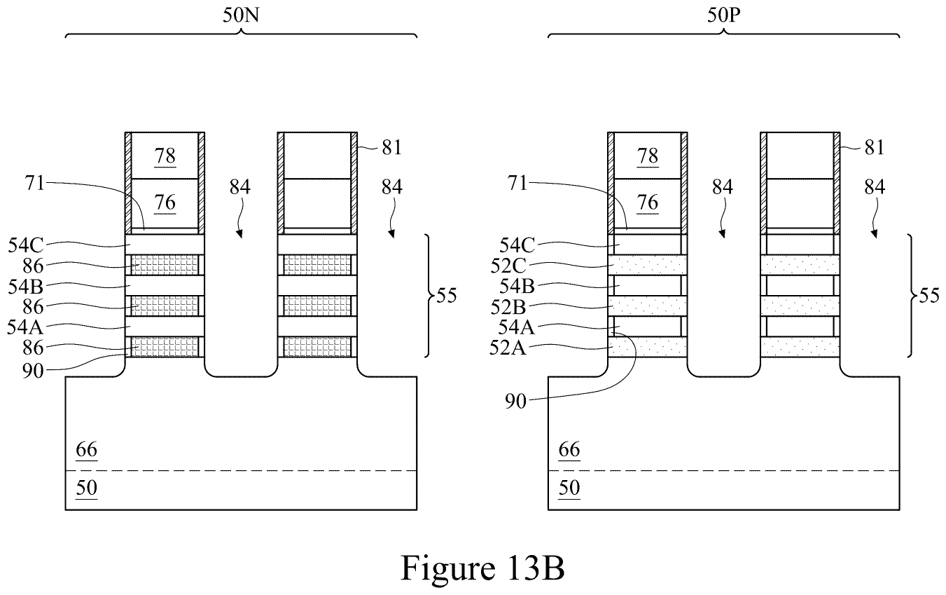

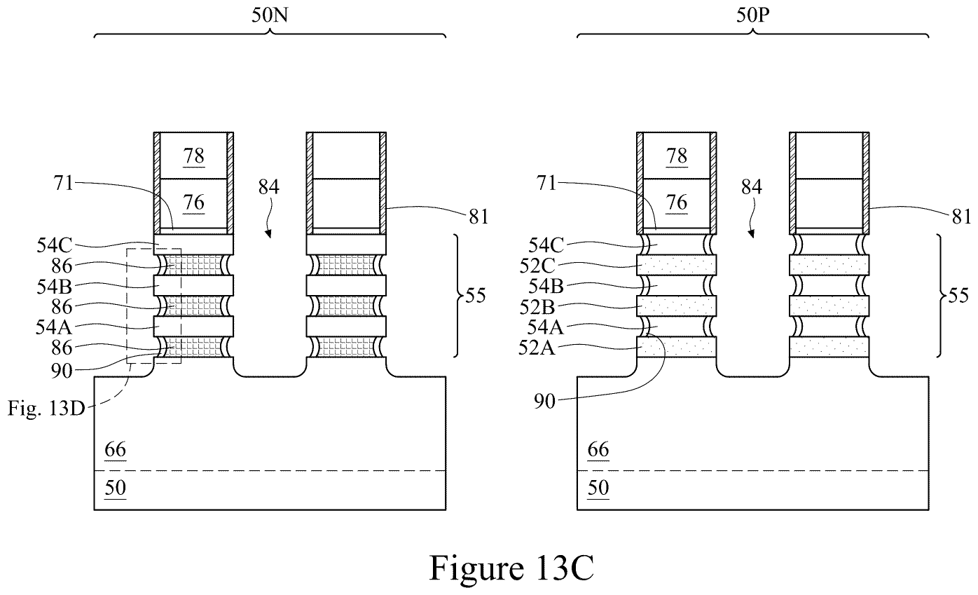

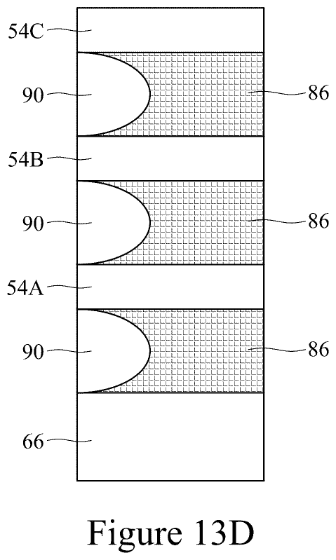

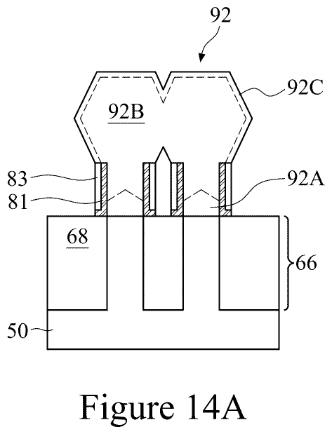

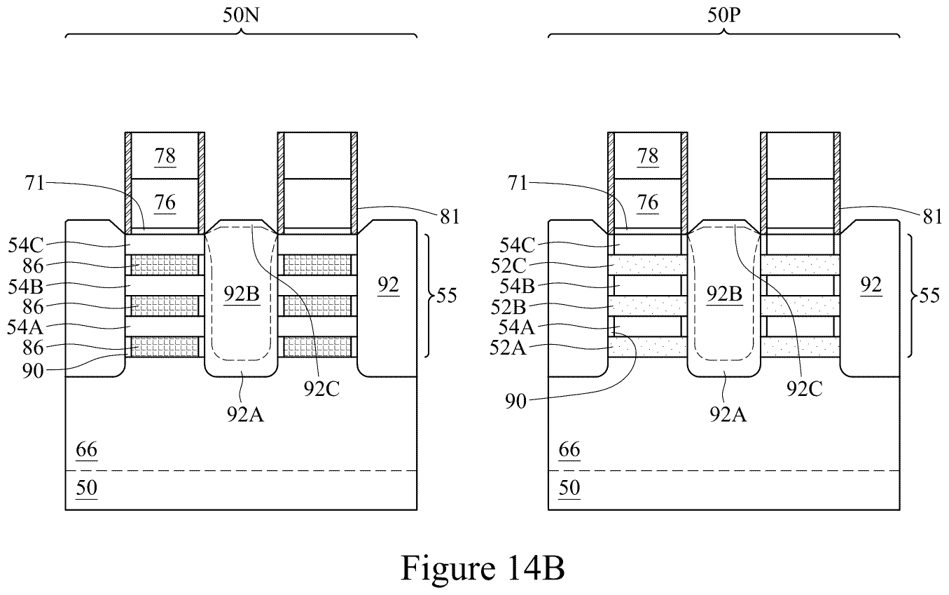

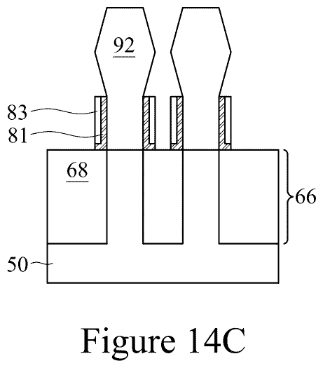

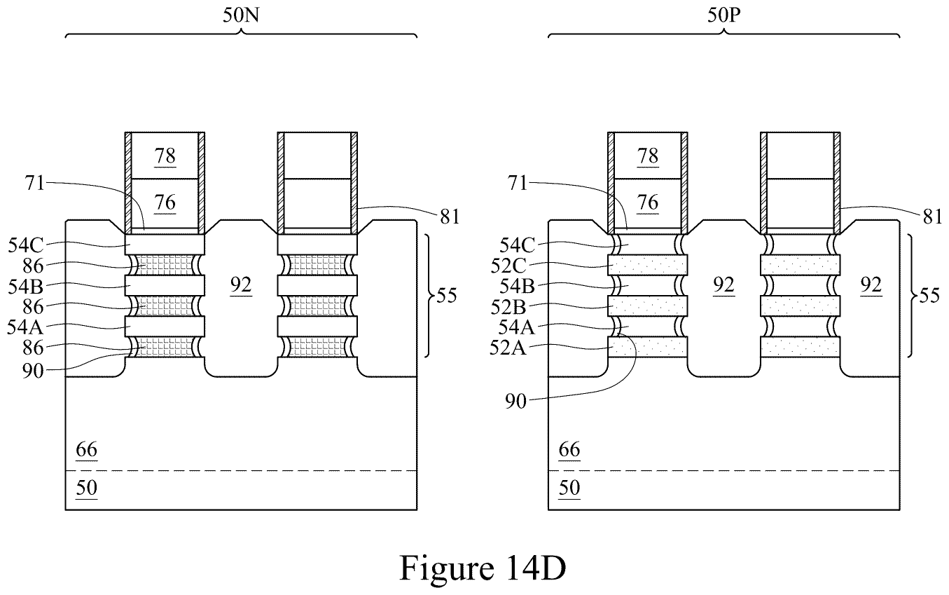

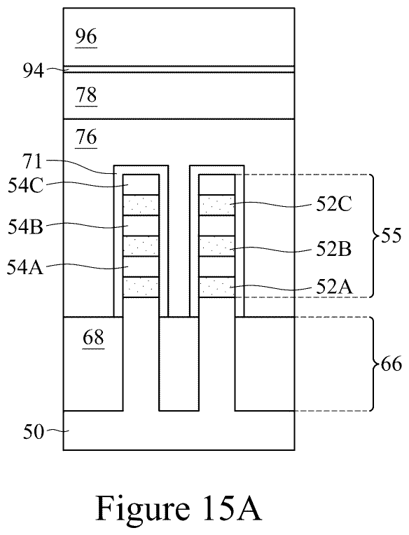

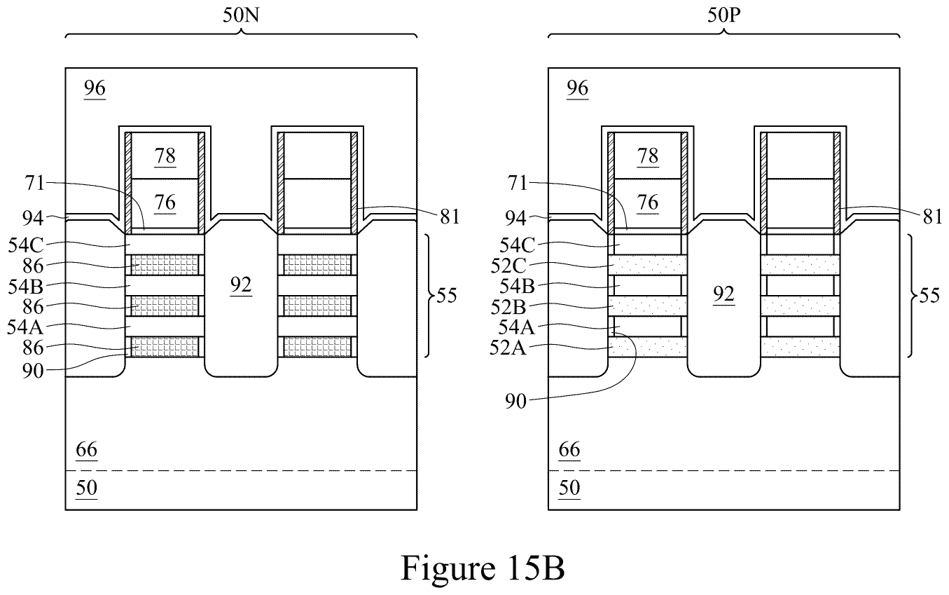

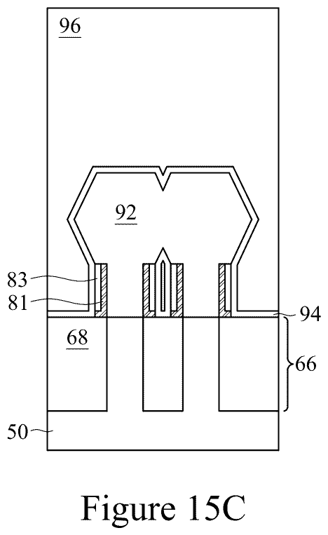

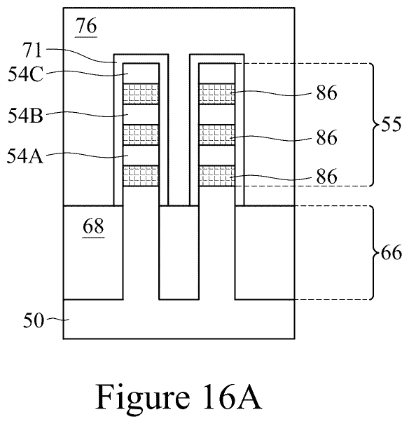

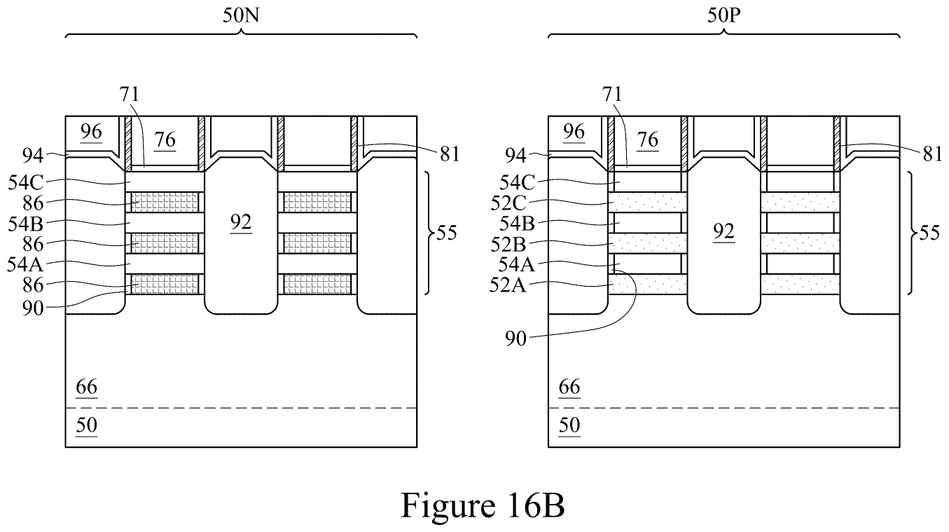

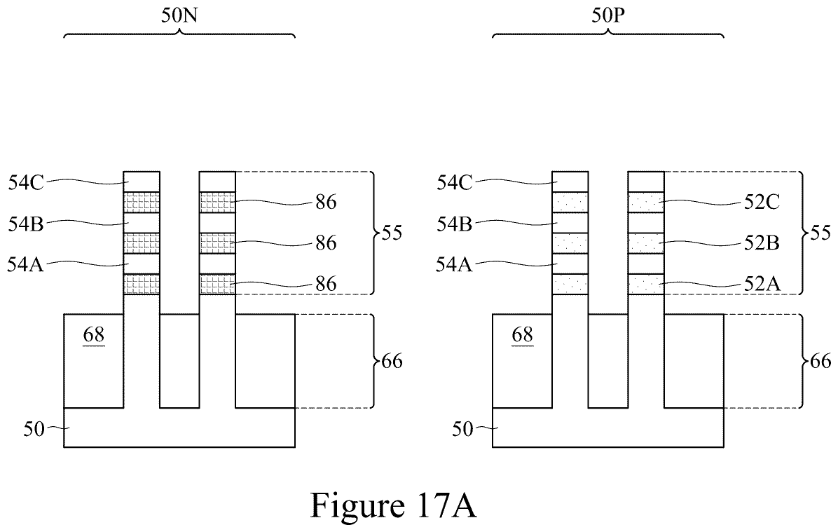

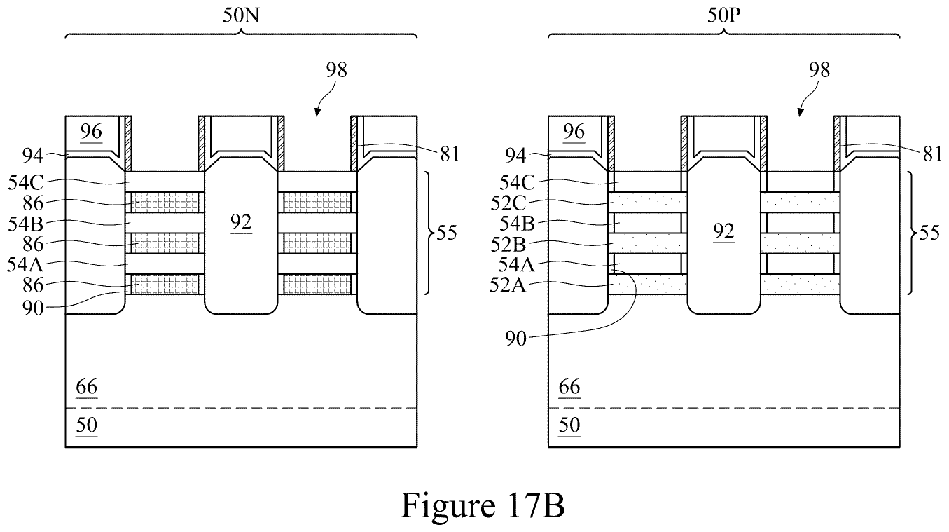

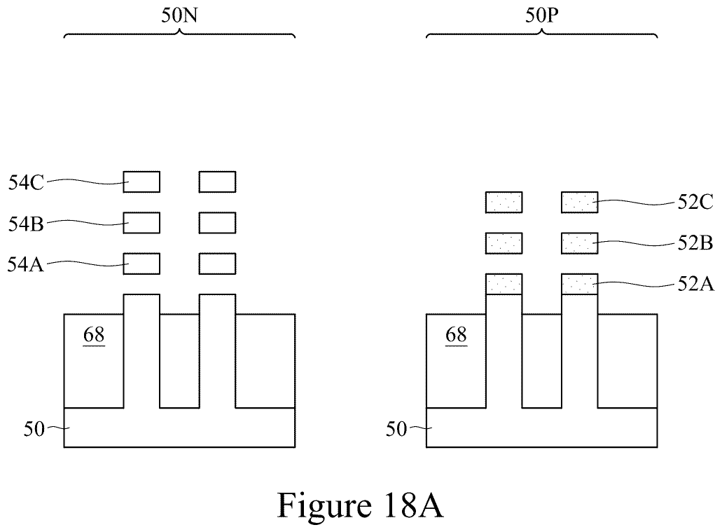

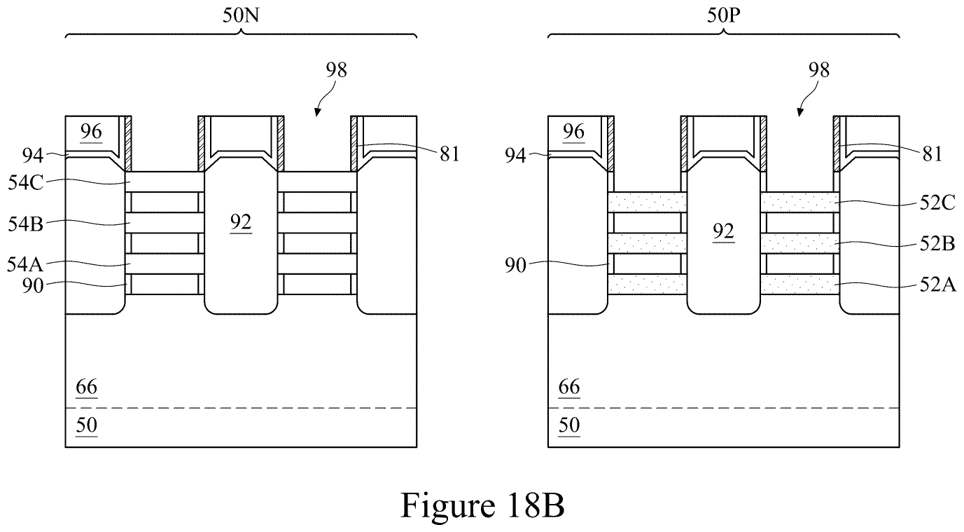

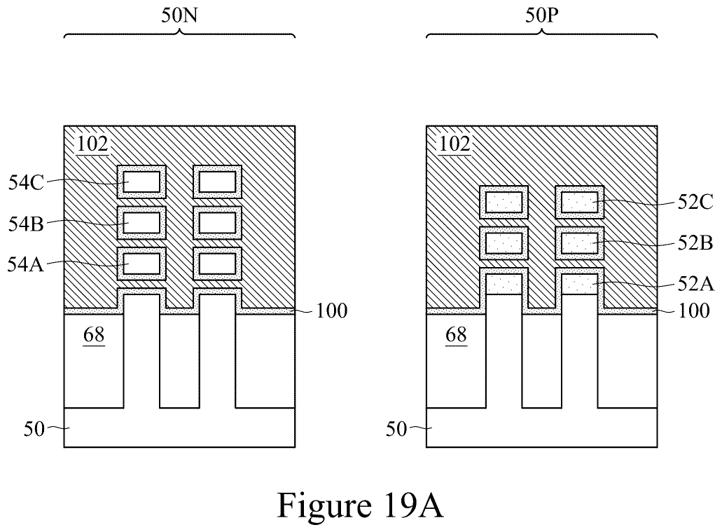

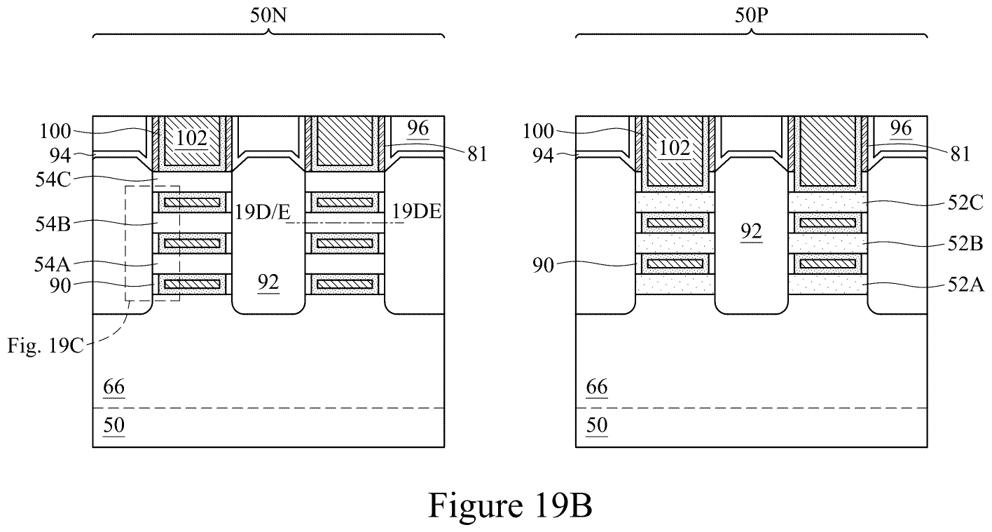

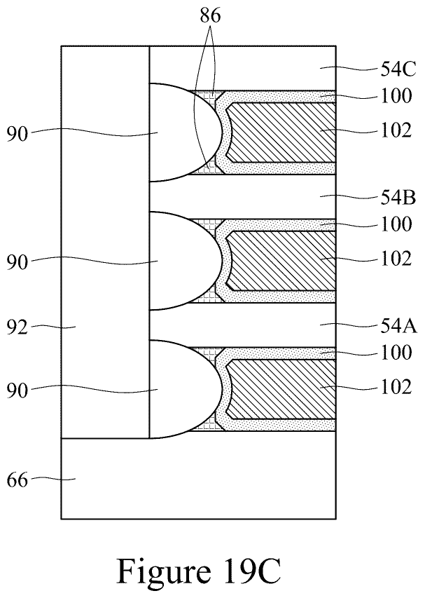

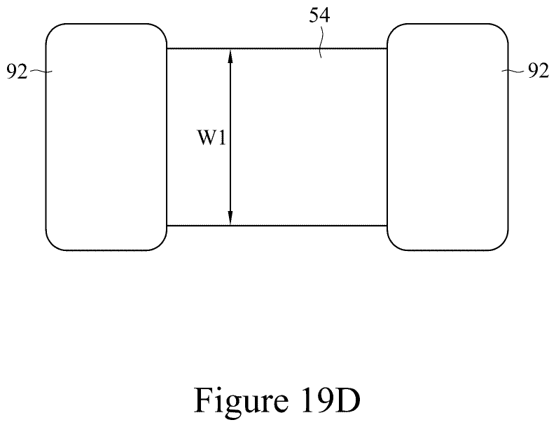

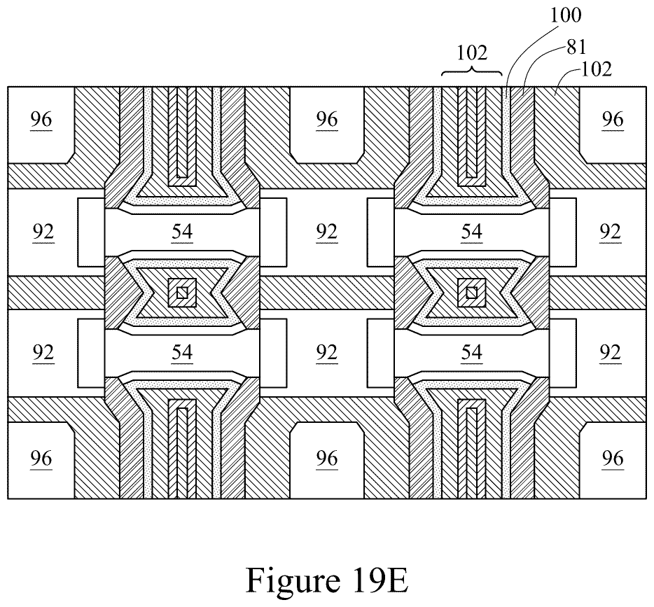

FIGS. 2A through 23C are cross-sectional views of intermediate stages in the manufacturing of nano-FETs, in accordance with some embodiments. FIGS. 2A, 2B, 3 through 5, 6A, 15A, 16A, 17A, 18A, 19A, 20A, 21A, 22A, and 23A illustrate reference cross-section A-A′ illustrated in FIG. 1. FIGS. 6B, 7B, 8B, 9B, 10B, 11B,, 12B,, 13B, 14B, 15B, 16B, 17B, 18B, 19B, 20B, 21B, 22B, and 23B illustrate reference cross-section B-B′ illustrated in FIG. 1. FIGS. 7A, 8A, 9A, 10A, 11A, 12A, 13A, 14A, 14C, 15C, 20C, 21C, 22C, and 23C illustrate reference cross-section C-C′ illustrated in FIG. 1.

In FIG. 2A, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs.

The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2A, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the second semiconductor layers 53 will be removed and the first semiconductor layers 51 will be patterned to form channel regions of nano-FETs in the p-type region 50P. Also, the first semiconductor layers 51 will be removed and the second semiconductor layers 53 will be patterned to form channel regions of nano-FETs in the n-type region 50N. Nevertheless, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P.

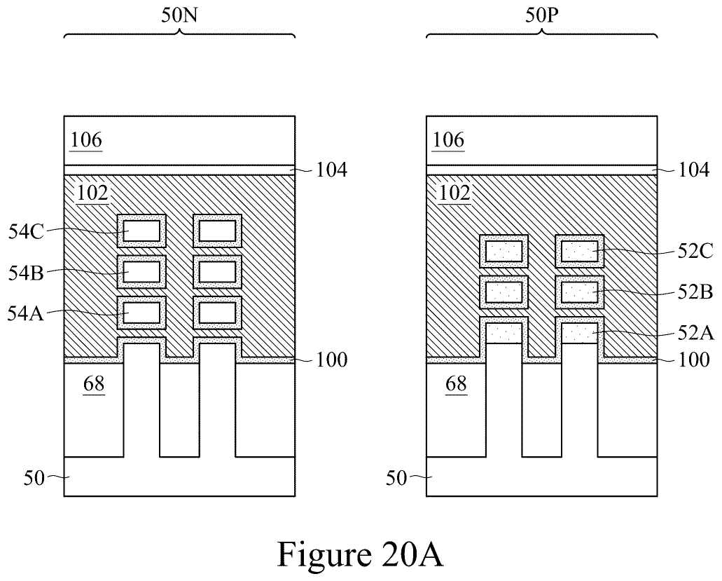

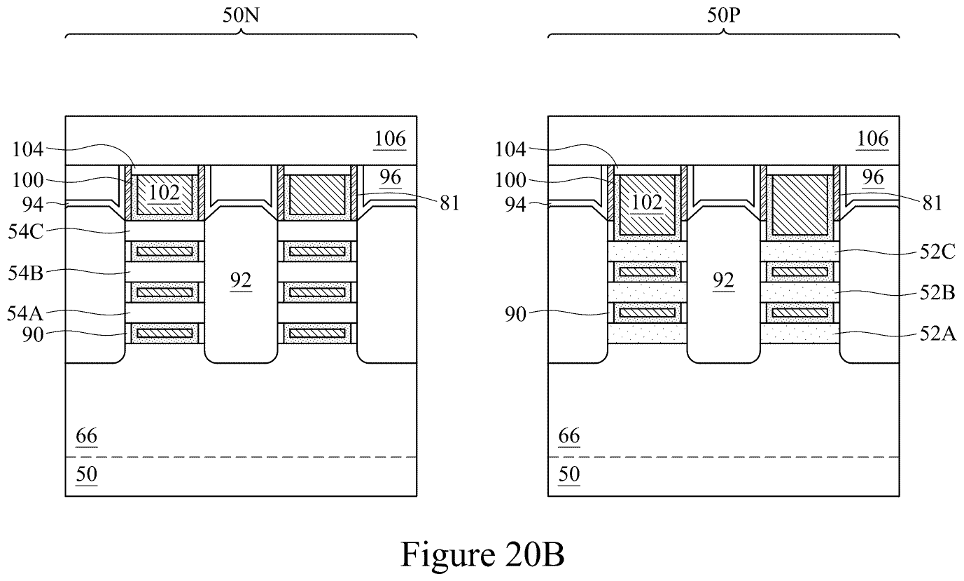

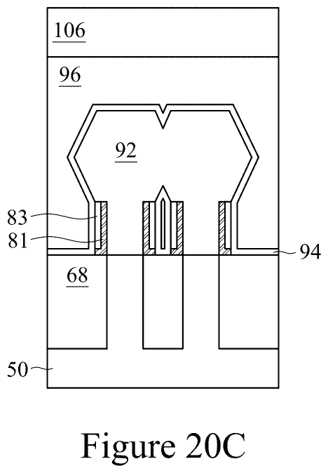

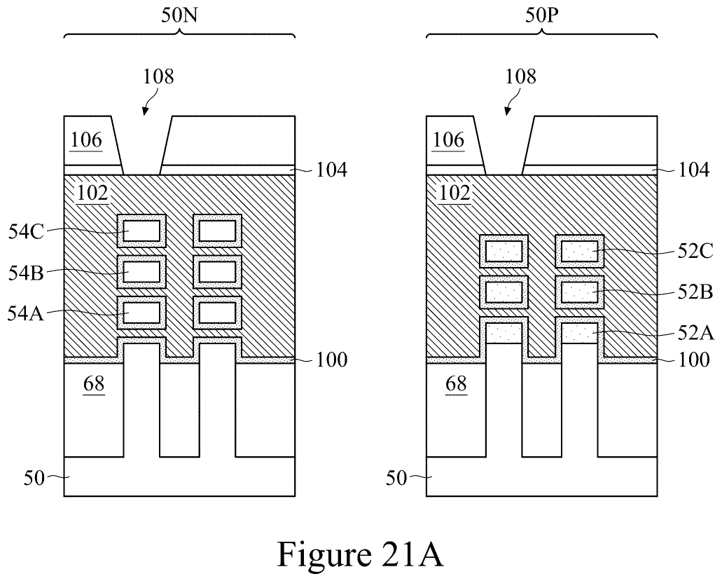

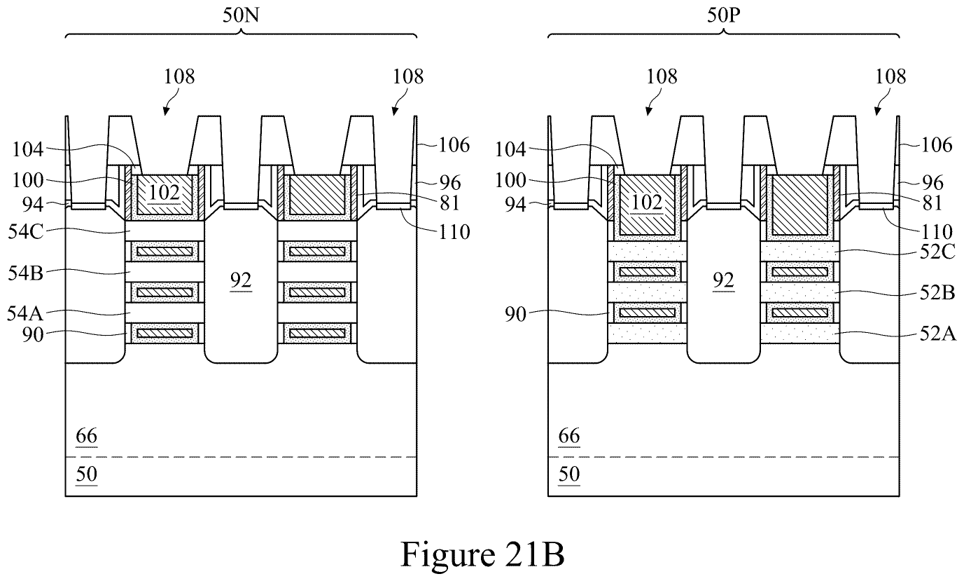

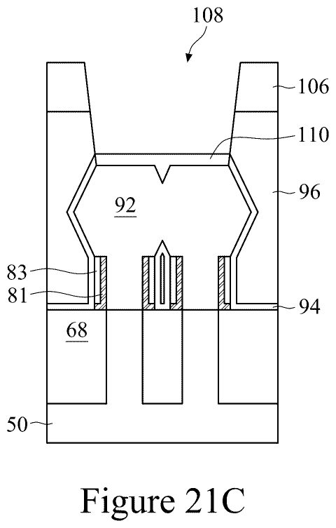

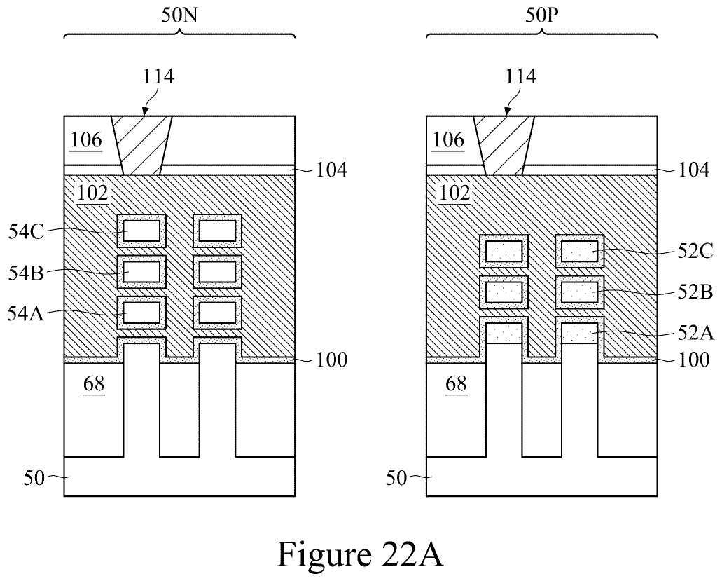

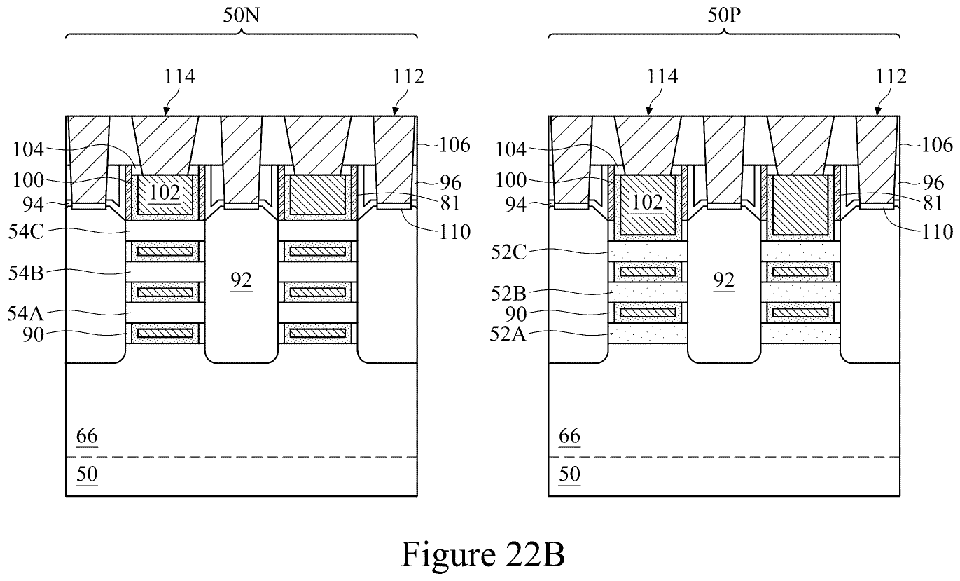

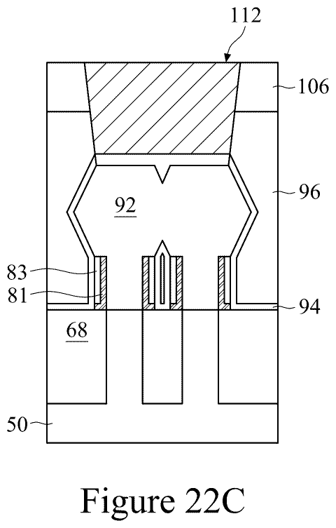

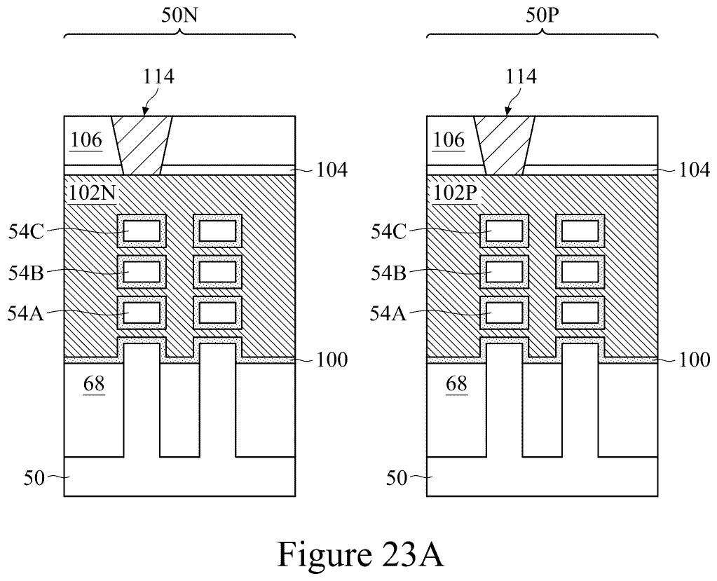

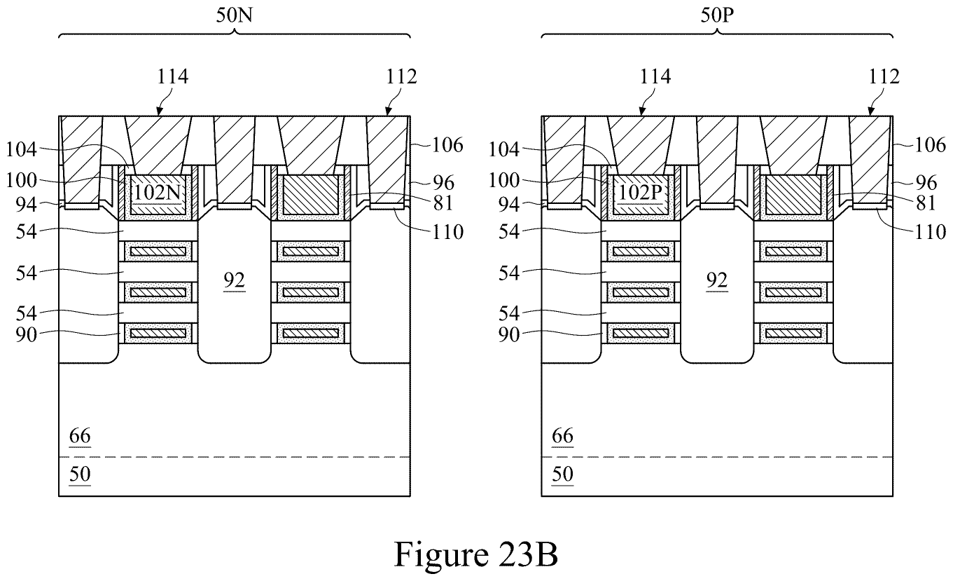

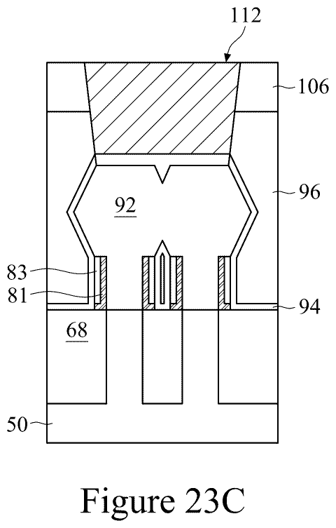

In still other embodiments, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of non-FETs in both the n-type region 50N and the p-type region 50P. In such embodiments, the channel regions in both the n-type region 50N and the p-type region 50P may have a same material composition (e.g., silicon, or another semiconductor material) and be formed simultaneously. FIGS. 23A, 23B, and 23C illustrate a structure resulting from such embodiments where the channel regions in both the p-type region 50P and the n-type region 50N comprise silicon, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

In some embodiments, the second semiconductor layers 53 may be formed such that the individual layers 53A, 53B, and 53C have different thicknesses. For example as shown in FIG. 2B, the semiconductor layer 53A has a thickness T1, the semiconductor layer 53B has a thickness T2, and the semiconductor layer 53C has a thickness T3. In some embodiments, the thickness T3 is greater than the thickness T2 which is greater than the thickness T1. In some embodiments, the thickness T2 is in a range from 1.3T1 to 1.4T1 and the thickness T3 is in a range from 1.5T1 to 1.6T1.

Although subsequent figures and embodiments may not be illustrated with second semiconductor layers 53 having different thicknesses, any of the disclosed figures or embodiments may include semiconductor layers 53 having different thicknesses as illustrated in FIG. 2B.

By engineering the sheet height, the disclose process can produce low, median, and high Vt devices within the same SRAM cell. This engineering of Vt is advantageous as it can lead to improved data retention, lower minimum operating voltages, reduced power consumption, and a smaller cell area, thereby enhancing the overall performance and efficiency of the SRAM device.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material in the n-type region 50N, thereby allowing the second semiconductor layers 53 to be patterned to form channel regions of n-type nano-FETs. Similarly, the second semiconductor layers 53 of the second semiconductor material may be removed without significantly removing the first semiconductor layers 51 of the first semiconductor material in the p-type region 50P, thereby allowing the first semiconductor layers 51 to be patterned to form channel regions of p-type nano-FETs.

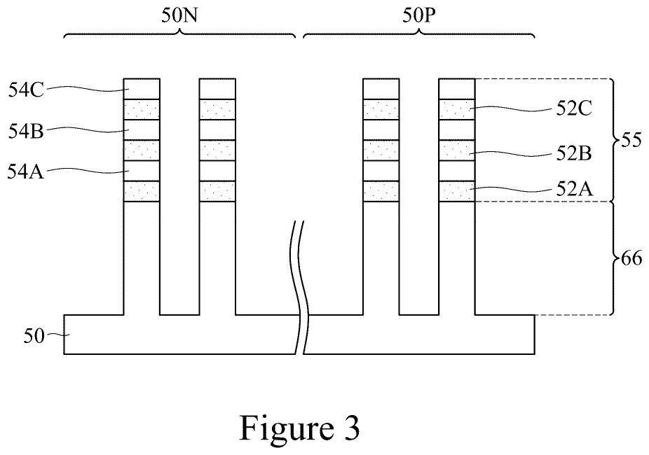

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

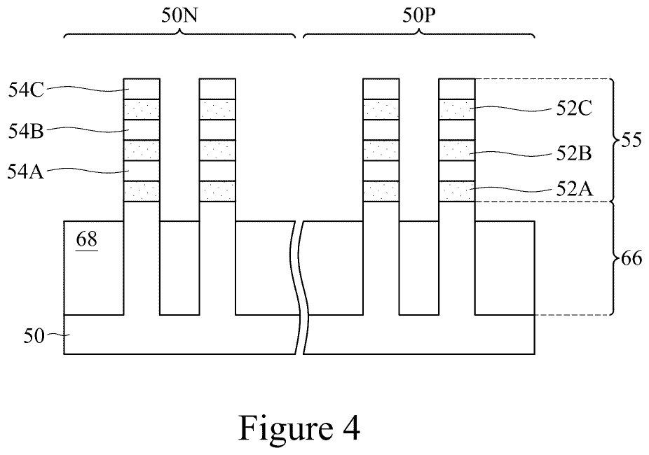

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, hydrogen fluoride, diluted hydrogen fluoride, another fluorine-based etchant, or the like may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting nanostructures 52) and the second semiconductor layers 53 (and resulting nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from 10¹³ atoms/cm³ to 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from 10¹³ atoms/cm³ to 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

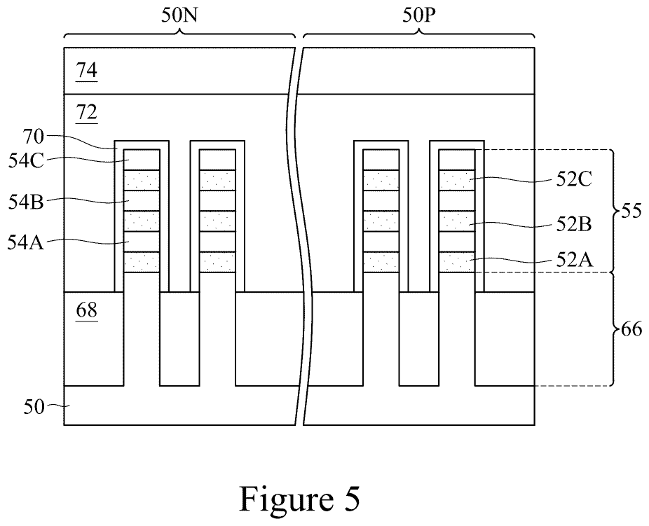

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 18C illustrate various additional steps in the manufacturing of embodiment devices. FIGS. 6A, 6B, 7A, 7B, 8A, 8B, 9A, 9B, 10A, 11A, 12A,, 13A, 13C, 14A, 15A, and 18C illustrate features in either the regions 50N or the regions 50P. FIGS. 10B, 11B, and 17A illustrate features in region 50N.

In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 1×10¹⁵ atoms/cm³ to 1×10¹⁹ atoms/cm³. An anneal may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A and 9B, first recesses 84 are formed in the fins 66, the nanostructures 55, and the substrate 50, in accordance with some embodiments. Epitaxial source/drain regions will be subsequently formed in the first recesses 84. The first recesses 84 may extend through the first nanostructures 52 and the second nanostructures 54, and into the substrate 50. As illustrated in FIG. 9A, top surfaces of the STI regions 58 may be level with bottom surfaces of the first recesses 84. In various embodiments, the fins 66 may be etched such that bottom surfaces of the first recesses 84 are disposed below the top surfaces of the STI regions 68; or the like. The first recesses 84 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 84. A single etch process or multiple etch processes may be used to etch each layer of the nanostructures 55 and/or the fins 66. Timed etch processes may be used to stop the etching of the first recesses 84 after the first recesses 84 reach a desired depth.

In FIGS. 10A and 10B, the first nanostructures 52 in the n-type region 50N are removed extending the first recesses 84. The first nanostructures 52 may be removed by forming a mask (not shown) over the p-type region 50P and performing an isotropic etching process such as wet etching or the like using etchants which are selective to the materials of the first nanostructures 52, while the second nanostructures 54, the substrate 50, the STI regions 58 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52 in the n-type region 50N.

In FIGS. 11A and 11B, a disposable material 86 is deposited in the first recesses 84 and spaces where the first nanostructures 52 were removed. The disposable material 86 may be deposited by a conformal deposition process, such as CVD, ALD, or the like. In some embodiments, the disposable material 86 may include one or more layers of silicon dioxide (SiO₂), silicon oxynitride (SiON), aluminum oxide (Al₂O₃), or the like. These materials are selected for their properties, such as etch selectivity, which allows for precise removal during the manufacturing process without adversely affecting the adjacent and underlying silicon structures. The choice of oxide material may depend on the requirements of the semiconductor device being fabricated and the electrical and physical properties of the final product.

In FIGS. 12A and 12B, portions of sidewalls of the disposable material 86 is etched to form sidewall recesses 88 in the n-type region 50N, and portions of sidewalls of the layers of the multi-layer stack 56 formed of the second semiconductor materials (e.g., the second nanostructures 54) exposed by the first recesses 84 are etched to form sidewall recesses 88 in the p-type region 50P. Although sidewalls of the disposable material 86 and the second nanostructures 54 in sidewall recesses 88 are illustrated as being straight in FIG. 12B, the sidewalls may be concave or convex (see e.g., FIG. 13C). The etching may be isotropic or anisotropic.

For example, the p-type region 50P may be protected using a mask (not shown) while etchants selective to the disposable material 86 are used to etch the disposable material 86 such that the second nanostructures 54 and the substrate 50 remain relatively unetched as compared to the disposable material 86 in the n-type region 50N. The disposable material 86 may be etched by a wet etch process using hydrogen fluoride, diluted hydrogen fluoride, another fluorine-based etchant, or the like as an etchant. In some embodiments, the recessing is performed by repeating a dry etching and wet etching process several times. In some embodiments, the etching is performed until sidewalls of the disposable material 86 is recessed past sidewalls of the nanostructures 54.

Similarly, the n-type region 50N may be protected using a mask (not shown) while etchants selective to the second semiconductor materials are used to etch the second nanostructures 54 such that the first nanostructures 52 and the substrate 50 remain relatively unetched as compared to the second nanostructures 54 in the p-type region 50P. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52 in the n-type region 50N, and a wet or dry etch process with hydrogen fluoride, another fluorine-based etchant, or the like may be used to etch sidewalls of the second nanostructures 54 in the p-type region 50P.

Replacing the first nanostructures 52 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. By replacing the first nanostructures 52 with an insulating material prior to the high temperature processes (e.g., source/drain annealing), manufacturing defects can be reduced and device performance can be improved.

In FIGS. 13A-13C, first inner spacers 90 are formed in the sidewall recess 88. The first inner spacers 90 may be formed by depositing an inner spacer layer (not separately illustrated) over the structures illustrated in FIGS. 12A and 12B. The first inner spacers 90 act as isolation features between subsequently formed source/drain regions and a gate structure. As will be discussed in greater detail below, source/drain regions will be formed in the first recesses 84, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

Moreover, although the outer sidewalls of the first inner spacers 90 are illustrated as being straight in FIG. 13B, the outer sidewalls of the first inner spacers 90 may be concave or convex. As an example, FIG. 13C illustrates an embodiment in which sidewalls of the disposable material 86 are concave, outer sidewalls of the first inner spacers 90 are concave, and the first inner spacers 90 are recessed from sidewalls of the second nanostructures 54 in the n-type region 50N. FIG. 13D is a detailed view of a portion of the embodiment of FIG. 13C with the inner spacers 90 have convex inner sidewalls facing the disposable material 86. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 14A-14D) by subsequent etching processes, such as etching processes used to form gate structures.

In FIGS. 14A-14D, epitaxial source/drain regions 92 are formed in the first recesses 84. In some embodiments, the source/drain regions 92 may exert stress on the second nanostructures 54 in the n-type region 50N and on the first nanostructures 52 in the p-type region 50P, thereby improving performance. As illustrated in FIG. 14B, the epitaxial source/drain regions 92 are formed in the first recesses 84 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 84 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 84 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between 1×10¹⁹ atoms/cm³ and 1×10²¹ atoms/cm³. The n-type and/or p-type impurities for source/drain regions may be any of the impurities previously discussed. In some embodiments, the epitaxial source/drain regions 92 may be in situ doped during growth.

For example, the source/drain regions 92 in the n-type region 50N may be implanted with a dopant P, As, Sb, and related dimers into the semiconductor material. The energy for the implantation process may range from 100 eV to 60 keV, which allows for control over the implantation depth and concentration of the dopants within the semiconductor material. The dosage of the dopants during the implantation process may vary between 1E¹³ to 1E¹⁶ atoms per square centimeter, which can be adjusted based on the desired electrical characteristics of the source/drain regions. The tilt angle during the implantation may be set between 0 to 85 degrees, providing flexibility in the distribution of the dopants within the semiconductor material. Temperature control during the implantation process is also considered, with a range from −300° C. to 500° C. In some embodiments, the implantation process may be performed at temperatures ranging from −300° C. to 30° C. to minimize thermal diffusion of the dopants and to maintain the integrity of the semiconductor structure. These implant conditions are designed to optimize the introduction of n-type dopants into the source/drain regions 92 of nano-FETs, thereby enhancing the electrical performance of the semiconductor device while minimizing potential defects and maintaining the structural integrity of the device.

In some embodiments, following the implantation of dopants into the source/drain regions 92 of the n-type region 50N, an anneal process may be performed to activate the implanted dopants and repair any damage caused by the implantation. The anneal process may involve heating the semiconductor device to a temperature ranging from 500° C. to 1500° C. The duration of the anneal process may vary from 0.1 nanoseconds to 10 hours, depending on the requirements of the device and the nature of the implanted species. The pressure during the anneal process may be controlled within a range from 1E⁻⁶ torr to 1E⁵ torr. The anneal process may be conducted in various environments, including but not limited to, inert atmospheres, reducing atmospheres, or oxidizing atmospheres, to achieve the desired electrical properties and structural integrity of the source/drain regions. The anneal conditions are selected to effectively activate the dopants while minimizing unwanted diffusion or activation of impurities, thereby optimizing the electrical performance of the nano-FETs and ensuring the formation of high-quality junctions within the semiconductor device.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 14A. In other embodiments, adjacent epitaxial source/drain regions 92 remain separated after the epitaxy process is completed as illustrated by FIG. 14C. In the embodiments illustrated in FIGS. 14A and 14C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 14D illustrates an embodiment in which sidewalls of the disposable material 86 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54 and the first nanostructures 52, respectively. As illustrated in FIG. 14D, the epitaxial source/drain regions 92 may be formed in contact with the first inner spacers 90 and may extend past sidewalls of the second nanostructures 54 in the n-type region 50N and past sidewalls of the first nanostructures 52 in the p-type region 50P.

In FIGS. 15A-15C, a first interlayer dielectric (ILD) 96 is deposited over the structure illustrated in FIGS. 6A, 14B, and 14A (the processes of FIGS. 7A-14D do not alter the cross-section illustrated in FIG. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

In FIGS. 16A-16C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

In FIGS. 17A and 17B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

In FIGS. 18A and 18B, the disposable material 86 in the n-type region 50N and the second nanostructures 54 in the p-type region 50P is removed. The disposable material 86 may be removed by forming a mask (not shown) over the p-type region 50P and performing an isotropic etching process such as wet etching or the like using etchants which are selective to the materials of the disposable material 86, while the second nanostructures 54 and the substrate 50 remain relatively unetched as compared to the disposable material 86. In embodiments in which the disposable material 86 include, e.g., SiO₂, and the second nanostructures 54A-54C include, e.g., Si or SiC, hydrogen fluoride, diluted hydrogen fluoride, another fluorine-based etchant, or the like may be used to remove the disposable material 86 in the n-type region 50N. In some embodiments, the removal of the disposable material 86 is performed by repeating a dry etching and wet etching process several times.

The second nanostructures 54 in the p-type region 50P may be removed by forming a mask (not shown) over the n-type region 50N and performing an isotropic etching process such as wet etching or the like using etchants which are selective to the materials of the second nanostructures 54, while the first nanostructures 52, the substrate 50, the STI regions 58 remain relatively unetched as compared to the second nanostructures 54. In embodiments in which the second nanostructures 54 include, e.g., SiGe, and the first nanostructures 52 include, e.g., Si or SiC, hydrogen fluoride, another fluorine-based etchant, or the like may be used to remove the second nanostructures 54 in the p-type region 50P.

In other embodiments, the channel regions in the n-type region 50N and the p-type region 50P may be formed simultaneously, for example, in these embodiments the disposable material 86 is replaces the first nanostructures 52 in both regions 50N and 50P, and the disposable material 86 can then be removed simultaneously in both the n-type region 50N and the p-type region 50P. In such embodiments, channel regions of n-type nano-FETs and p-type nano-FETS may have a same material composition, such as silicon, silicon germanium, or the like. FIGS. 23A, 23B, and 23C illustrate a structure resulting from such embodiments where the channel regions in both the p-type region 50P and the n-type region 50N are provided by the second nanostructures 54 and comprise silicon, for example.

In FIGS. 19A and 19B, gate dielectric layers 100 and gate electrodes 102 are formed for replacement gates. FIG. 19C is a detailed view of a portion of FIG. 19B in accordance with some embodiments. FIG. 19D is a plan view of a second nanostructure 54 and source/drain regions 92 along line 19D-19D of FIG. 19B. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54, and in the p-type region 50P, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI regions 58.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 19A and 19B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 19C illustrates a detailed view of embodiments with the inner spacers 90 having convex inner sidewalls. In some embodiments, after the disposable material 86 is removed and replaced by the gate structures, some disposable material 86 remains between the inner spacers 90 and the gate structures. Because the DOI process was used, there is only oxide remaining between the inner spacers 90 and the gate structures and not germanium residue. This allows for a more selective etch process to be used during the replacement gate process and minimizes the possibility of metal gate extrusion.

FIG. 19D illustrates a plan view of a second nanostructure 54 and source/drain regions 92. The other structures are omitted from this view. In some embodiments, the second nanostructure 54 has a width W1. The width W1 may be consistent and uniform from one source/drain region 92 to another source/drain region 92 without significant reductions in portions of the second nanostructure 54. Said another way, the sidewall of the second nanostructure 54 between the source/drain regions 92 is a flat sidewall.

FIG. 19E illustrates a plan view of multiple second nanostructures 54, source/drain regions 92, gate dielectric layers 100, and gate electrodes 102. As discussed above in FIG. 19D, the widths of the second nanostructures 54 is consistent and uniform from one source/drain region 92 to another source/drain region 92 without significant reductions in portions of the second nanostructure 54. Said another way, the sidewalls of the second nanostructures 54 between the source/drain regions 92 and facing the gate electrodes 102 are flat sidewalls.

By utilizing the disposable oxide interposer (DOI) process, the n-type metal gate (NMG) extrusion is reduced. The DOI process replaces silicon germanium (SiGe) with an oxide material, which mitigates the diffusion of germanium into the silicon channel. This reduction in germanium diffusion is advantageous as it minimizes the risk of NMG extrusion defects, which can adversely affect the electrical performance and reliability of the nano-FETs. Moreover, the higher etch selectivity of the oxide material compared to SiGe allows for a more controlled and less invasive removal process, preserving the integrity of the silicon nanostructures, such as the height and width of the nanostructures. Consequently, the nanostructures retain their designed height, contributing to a reduction in channel resistance and an enhancement in device performance. The DOI process thus enables the fabrication of nano-FETs with improved structural and electrical characteristics, leading to semiconductor devices with improved performance metrics.

In FIGS. 20A-20C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 22A-22C) penetrate through the gate mask 104 to contact the top surface of the recessed gate electrodes 102.

As further illustrated by FIGS. 20A-20C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 21A-21C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 21B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between 2 nm and 10 nm.

Next, in FIGS. 22A-22C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIGS. 23A-23C illustrate cross-sectional views of a device according to some alternative embodiments. FIG. 23A illustrates reference cross-section A-A′ illustrated in FIG. 1. FIG. 23B illustrates reference cross-section B-B′ illustrated in FIG. 1. FIG. 23C illustrates reference cross-section C-C′ illustrated in FIG. 1. In FIGS. 23A-23C, like reference numerals indicate like elements formed by like processes as the structure of FIGS. 22A-22C. However, in FIGS. 23A-C, channel regions in the n-type region 50N and the p-type region 50P comprise a same material. For example, the second nanostructures 54, which comprise silicon, provide channel regions for p-type nano-FETs in the p-type region 50P and for n-type nano-FETs in the n-type region 50N. The structure of FIGS. 23A-C may be formed, for example, by replacing the first nanostructures 52 from both the p-type region 50P and the n-type region 50N simultaneously with disposable material 86; removing the disposable material 86 from both the p-type region 50P and the n-type region 50N simultaneously; depositing the gate dielectric layers 100 and the gate electrodes 102P (e.g., gate electrode suitable for a p-type nano-FET) around the second nanostructures 54 in the p-type region 50P; and depositing the gate dielectric layers 100 and the gate electrodes 102N (e.g., a gate electrode suitable for a n-type nano-FET) around the second nanostructures 54 in the n-type region 50N. In such embodiments, materials of the epitaxial source/drain regions 92 may be different in the n-type region 50N compared to the p-type region 50P as explained above.

Embodiments may achieve advantages. The present disclosure introduces a Disposable Oxide Interposer (DOI) process for enhancing data retention in Static Random Access Memory (SRAM) devices, particularly those utilizing technologies smaller than 10 nm. The DOI process addresses the technical problem of inconsistent sheet heights in SRAM devices. This process involves the removal of SiGe layers from the Si/SiGe multilayer stack, filling the area with oxide, recessing or trimming the oxide vertically between Si sheets, and depositing and trimming inner spacers on the sidewalls of the recessed oxide. The DOI process improves the uniformity of the sheet heights and widths and allows for engineering of the sheet heights to have different heights in the same nano-FET stack. These different sheet heights in the same device stack enables the transition from all the same Vt devices to low, median, and high Vt devices. These improvements result in enhanced SRAM data retention, improved SRAM Vccmin, reduced power consumption, and reduced cell area.

For example, by utilizing the Disposable Oxide Interposer (DOI) process, the higher etch selectivity of the oxide material compared to SiGe allows for a more controlled and less invasive removal process, preserving the integrity of the silicon nanostructures. Consequently, the nanostructures retain a larger height, contributing to a reduction in channel resistance and an enhancement in device performance. The DOI process thus enables the fabrication of nano-FETs with improved structural and electrical characteristics, leading to semiconductor devices with improved performance metrics.

In an embodiment, a method may include forming a multi-layer stack over a substrate, the multi-layer stack having alternating layers of first semiconductor layers and second semiconductor layers. The method may also include removing the first semiconductor layers in a first region of the substrate. Furthermore, the method may include forming a disposable material between the second semiconductor layers in the first region. In addition, the method may include forming source/drain regions adjacent to the second semiconductor layers and the disposable material in the first region. Moreover, the method may include replacing the disposable material in the first region with metal gate structures, each of the second semiconductor layers having a different thickness.

The described embodiments may also include one or more of the following features: the method where the disposable material is selected from a group having silicon oxide, silicon oxynitride, and aluminum oxide. The method may include performing an ion implantation process to introduce n-type dopants into the source/drain regions after forming the disposable material between the second semiconductor layers. The second semiconductor layers may include a bottom layer, a middle layer over the bottom layer, and a top layer over the middle layer, the top layer being thicker than the bottom layer. The bottom layer has a first thickness, the middle layer has a second thickness, and the top layer has a third thickness, the second thickness being from 13 to 14 times the first thickness, and the third thickness being from 15 to 16 times the first thickness. The bottom layer has a different threshold voltage than the top layer. The bottom layer has a higher threshold voltage than the top layer. Replacing the disposable material in the first region with metal gate structures may further include removing the disposable material using an etching process that is selective to the disposable material over the second semiconductor layers. The method may include forming inner spacers on the sidewalls of the disposable material before forming the source/drain regions. The inner spacers may include silicon nitride, silicon oxynitride, or a combination thereof. The inner spacers have a convex shape facing the disposable material. The method may include replacing the second semiconductor layers with metal gate structures in a second region of the substrate.

In an embodiment, a method may include forming fins of a multi-layer stack over a substrate, the multi-layer stack including alternating layers of first semiconductor layers and second semiconductor layers. The method may also include forming first gate structures over the fins. Furthermore, the method may include etching first recesses into the fins in a first region and a second region of the substrate. In addition, in the first region of the substrate, the method may include removing the first semiconductor layers and forming a disposable material between the second semiconductor layers. Moreover, the method may include forming source/drain regions in the first recesses adjacent to the disposable material and the second semiconductor layers in the first region and adjacent to the first semiconductor layers and the second semiconductor layers in the second region. The method may also include replacing the first gate structures and the disposable material in the first region with a first set of metal gate structures, the second semiconductor layers having a top layer and a bottom layer in the first region, the top layer having a different thickness than the bottom layer. The method may furthermore include replacing the first gate structures and the first semiconductor layers in the second region with a second set of metal gate structures.

The described embodiments may also include one or more of the following features: the method where the first set of metal gate structures is for n-type nano-FETs and the second set of metal gate structures is for p-type nano-FETs. The disposable material is selected from a group having silicon oxide, silicon oxynitride, and aluminum oxide. The bottom layer has a higher threshold voltage than the top layer. The top layer is thicker than the bottom layer.

In an embodiment, a semiconductor device may include a source region and a drain region over a substrate. The semiconductor device may also include a channel region between the source region and the drain region, the channel region having a stack of semiconductor layers where the stack includes a bottom semiconductor layer having a first thickness. The semiconductor device may also include a middle semiconductor layer over the bottom semiconductor layer, the middle semiconductor layer having a second thickness greater than the first thickness. The semiconductor device may moreover include a top semiconductor layer over the middle semiconductor layer, the top semiconductor layer having a third thickness greater than the second thickness, each of the first, second, and third thicknesses being measured in a direction perpendicular to a major surface of the substrate, where each of the semiconductor layers in the stack has flat sidewalls in a plan view between the source region and the drain region. The semiconductor device may also include a gate structure surrounding the stack of semiconductor layers.

The described embodiments may also include one or more of the following features: the second thickness is from 13 to 14 times the first thickness, and the third thickness is from 15 to 16 times the first thickness. The bottom semiconductor layer has a first threshold voltage, the middle semiconductor layer has a second threshold voltage different from the first threshold voltage, and the top semiconductor layer has a third threshold voltage different from the first and second threshold voltages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a multi-layer stack over a substrate, the multi-layer stack comprising alternating layers of first semiconductor layers and second semiconductor layers;
removing the first semiconductor layers in a first region of the substrate;
forming a disposable material between the second semiconductor layers in the first region;
forming source/drain regions adjacent second semiconductor layers and the disposable material in the first region; and
replacing the disposable material in the first region with metal gate structures, each of the second semiconductor layers having a different thickness.

2. The method of claim 1, wherein the disposable material is selected from a group consisting of silicon oxide, silicon oxynitride, and aluminum oxide.

3. The method of claim 1, further comprising:
performing an ion implantation process to introduce n-type dopants into the source/drain regions after forming the disposable material between the second semiconductor layers.

4. The method of claim 1, wherein the second semiconductor layers comprises a bottom layer, a middle layer over the bottom layer, and a top layer over the middle layer, the top layer of being thicker than the bottom layer.

5. The method of claim 4, wherein the bottom layer has a first thickness, the middle layer has a second thickness, and the top layer has a third thickness, the second thickness being from 1.3 to 1.4 times the first thickness and the third thickness being from 1.5 to 1.6 times the first thickness.

6. The method of claim 4, wherein the bottom layer has a different threshold voltage than the top layer.

7. The method of claim 6, wherein the bottom layer has a higher threshold voltage than the top layer.

8. The method of claim 1, wherein replacing the disposable material in the first region with metal gate structures further comprises:
removing the disposable material using an etching process that is selective to the disposable material over the second semiconductor layers.

9. The method of claim 1, further comprising:
forming inner spacers on sidewalls of the disposable material before forming the source/drain regions.

10. The method of claim 9, wherein the inner spacers comprise silicon nitride, silicon oxynitride, or a combination thereof.

11. The method of claim 9, wherein the inner spacers have a convex shape facing the disposable material.

12. The method of claim 1 further comprising:
replacing the second semiconductor layers with metal gate structures in a second region of the substrate.

13. A method, comprising:
forming fins of a multi-layer stack over a substrate, the multi-layer stack including alternating layers of first semiconductor layers and second semiconductor layers;
forming first gate structures over the fins;
etching first recesses into the fins in a first region and a second region of the substrate;
in the first region of the substrate, removing the first semiconductor layers and forming a disposable material between the second semiconductor layers;
forming source/drain regions in the first recesses adjacent to the disposable material and the second semiconductor layers in the first region and adjacent to the first semiconductor layers and the second semiconductor layers in the second region;
replacing the first gate structures and the disposable material in the first region with a first set of metal gate structures, the second semiconductor layers comprising a top layer and a bottom layer in the first region, the top layer having a different thickness than the bottom layer; and
replacing the first gate structures and the first semiconductor layers in the second region with a second set of metal gate structures.

14. The method of claim 13, wherein the first set of metal gate structures is for n-type nano-FETs and the second set of metal gate structures is for p-type nano-FETs.

15. The method of claim 13, wherein the disposable material is selected from a group consisting of silicon oxide, silicon oxynitride, and aluminum oxide.

16. The method of claim 13, wherein the bottom layer has a higher threshold voltage than the top layer.

17. The method of claim 16, wherein the top layer is thicker than the bottom layer.

18. A semiconductor device, comprising:
a source region and a drain region over a substrate;
a channel region between the source region and the drain region, the channel region comprising a stack of semiconductor layers, wherein the stack includes:
a bottom semiconductor layer having a first thickness;
a middle semiconductor layer over the bottom semiconductor layer, the middle semiconductor layer having a second thickness greater than the first thickness; and
a top semiconductor layer over the middle semiconductor layer, the top semiconductor layer having a third thickness greater than the second thickness, each of the first, second, and third thicknesses being measured in a direction perpendicular to a major surface of the substrate, wherein each of the semiconductor layers in the stack has flat sidewalls in a plan view between the source region and the drain region; and
a gate structure surrounding the stack of semiconductor layers.

19. The semiconductor device of claim 18, wherein the second thickness is from 1.3 to 1.4 times the first thickness, and the third thickness is from 1.5 to 1.6 times the first thickness.

20. The semiconductor device of claim 18, wherein:
the bottom semiconductor layer has a first threshold voltage;
the middle semiconductor layer has a second threshold voltage different from the first threshold voltage; and
the top semiconductor layer has a third threshold voltage different from the first and second threshold voltages.
